(19) United States
(12) Patent Application Publication
(10) Pub. No.: US 2026/0130141 A1
(43) Pub. Date: May 7, 2026

(54) METHOD AND SYSTEM FOR SELECTIVE DEPOSITION OF DIELECTRIC MATERIAL ON METAL SURFACE

(71) Applicant: ASM IP Holding B.V., Almere (NL)

(72) Inventors: Adam Vianna, Phoenix, AZ (US); Krzysztof Kamil Kachel, Chandler, AZ (US); Aaron McLeod, Phoenix, AZ (US); Leonard Rodriguez, Phoenix, AZ (US); Kristina Paula Martinez, Phoenix, AZ (US)

(21) Appl. No.: 19/373,954

(22) Filed: Oct. 30, 2025

Related U.S. Application Data
(60) Provisional application No. 63/716,123, filed on Nov. 4, 2024.

(51) Int. Cl. H01L 21/02; C23C 16/04; C23C 16/52; H01J 37/32

(52) U.S. Cl. CPC H10P 14/6682; C23C 16/04; C23C 16/52; H01J 37/3244; H10P 14/6339; H10P 14/6687; H10P 14/6922; H01J 2237/332

(57) ABSTRACT

A method of selectively depositing a dielectric material on a metal surface relative to a non-metal surface is disclosed. An exemplary method includes using a first reactant to selectively form desired terminal functional groups on the non-metal surface and selectively reacting a second reactant with the terminal functional groups to selectively form an organic layer on the non-metal surface.

### CROSS-REFERENCE TO RELATED APPLICATIONS

This application is a nonprovisional of, and claims priority to and the benefit of, U.S. Provisional Patent Application No. 63/716,123, filed Nov. 4, 2024 and entitled “METHOD AND SYSTEM FOR SELECTIVE DEPOSITION OF DIELECTRIC MATERIAL ON METAL SURFACE,” which is hereby incorporated by reference herein.

### FIELD OF INVENTION

The present disclosure generally relates to methods for depositing material on a substrate. More particularly, the disclosure relates to selectively depositing dielectric material on a metal surface utilizing a selectively formed passivation film.

### BACKGROUND OF THE DISCLOSURE

Dielectric material films or layers are used for a wide variety of applications. For example, dielectric material films can be used to form insulating regions, diffusion barriers, surface passivation, and formation of various device components, such as gate structures, capacitors, and the like.

To form the regions or features including dielectric material, dielectric material is typically deposited onto a surface of a substrate. The deposited film is then patterned using, for example, photolithography, and then the film is etched to remove some of the dielectric material to form desired features or areas including the remaining dielectric material. As device features continue to decrease in size, it becomes increasingly difficult to pattern and etch dielectric material films to form features or areas of patterned dielectric material of desired dimensions, particularly when it is desired to deposit dielectric material within a via or trench on a substrate surface. Additionally, lithography and etch steps can increase costs associated with device manufacturing and increase an amount of time required for device fabrication.

Accordingly, improved methods are desired for selectively forming dielectric material on metal surfaces.

### SUMMARY OF THE DISCLOSURE

This section introduces a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure provide methods and reactor systems for selectively depositing a dielectric material on a metal surface relative to a non-metal surface. As set forth in more detail below, the selective deposition can be obtained by selectively forming a blocking or passivation layer on the non-metal surface relative to the metal surface. The blocking or passivation layer can prevent or mitigate unwanted deposition of dielectric material on the non-metal surface.

In accordance with various embodiments of the disclosure, a method of depositing a dielectric material on a metal surface relative to a non-metal surface includes providing a substrate within a reaction chamber of a reactor, providing a first reactant to the reaction chamber, and providing a second reactant to the reaction chamber. In accordance with examples of the disclosure, the first reactant selectively reacts with the non-metal surface, relative to the metal surface, to form —OSiH functional groups on the non-metal surface and the second reactant selectively reacts with the —OSiH functional groups, relative to the metal surface, to selectively form an organic layer on the non-metal surface, relative to the metal surface. The organic layer can serve as a passivation or blocking layer for subsequent deposition of dielectric material onto the metal surface. In accordance with further examples, the first reactant is or includes an amino silane. In some cases, the second reactant can include an alkene and/or or an alkyne terminal functional group. In some cases, the second reactant is represented by the formula CₓH_{y}F_{z}, where X is a whole number between about 2 and about 24 or between about 2 and about 18 or between about 2 and about 12, y is a whole number between about 0 and about 36 or between about 1 and about 24 or between about 1 and about 12, and z is 0 or a whole number between about 0 and about 36 or between about 1 and about 24 or between about 1 and about 12. In some cases, the second reactant is or includes a thiol. In some cases, the second reactant is or includes a disulfide. In some cases, the second reactant is or includes an alcohol. In some cases, the second reactant is or includes an aldehyde. In some cases, the second reactant comprises one or more of (1) a C2-C18 alkene or alkyne or a fluorine-substituted derivative thereof, (2) a sulfur compound, (3) an alcohol, or (4) an aldehyde. The method can also include a step of selectively depositing the dielectric material on the metal surface. The method can further include, after selectively depositing the dielectric material on the metal surface, removing the organic layer.

In accordance with further embodiments, a reactor system includes a controller, a source vessel comprising the first reactant and coupled to the reaction chamber, a source vessel comprising the second reactant and coupled to the reaction chamber, the reactor, and a vacuum source. The controller can be configured to perform or have the reactor system perform a method as described herein.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with various embodiments of the disclosure.

FIG. 2 illustrates a substrate and a substrate surface in accordance with various embodiments of the disclosure.

FIG. 3 illustrates method steps in accordance with various embodiments of the disclosure.

FIG. 4 illustrates method steps in accordance with additional embodiments of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to a method of selectively depositing a dielectric material on a metal surface relative to a non-metal surface. The method can form selectively deposited dielectric material on the metal surface without patterning and etching steps.

Selectivity can be described as a percentage calculated as [(amount of deposition on first surface)−(amount of deposition on second surface)]/(amount of deposition on the first surface). An amount of deposition can be, for example, a measured thickness of the deposited material or a mass of the deposited material.

As used herein, the term substrate may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

As used herein, the term metal surface may refer to surfaces including a metal component, including, but not limited to, metal surfaces, metal alloy surfaces, and other surfaces that include a metal and that are conductive (e.g., have a resistivity of less than 100 μΩ cm). In some cases, the term metal surface may include a surface of native oxide of a metal. In some cases, the metal surface comprises a metallic material. In some cases, the metal surface consists essentially of one or more of a metal or a metal alloy. By way of particular examples, the metal surface can include one or more of molybdenum, cobalt, ruthenium, copper, titanium, tantalum, or tungsten, in elemental metal or alloy form.

As used herein, the term non-metal surface may refer to a surface including primarily non-metal and/or non-conductive (e.g., resistivity greater than 500 ohm-cm) material. Such non-metal surfaces can include metalloids and/or an oxide, nitride, or carbide thereof. By way of example, the non-metal surface can include one or more silicon containing materials, such as, for example, silicon, a silicon oxide, a silicon nitride, a silicon oxynitride, a silicon oxycarbide, mixtures thereof, or the like.

In some embodiments, the term film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

As used herein, an organic layer includes carbon that is covalently bonded to another atom. An organic layer can be a hydrocarbon layer, an organo-sulfur layer, and/or a fluorine substituted hydrocarbon or fluorine substituted organo-sulfur compound.

In this disclosure, the term gas may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space, and may include a seal gas, such as a rare gas.

The term cyclic deposition process or cyclical deposition process may refer to the sequential introduction of precursors (and/or reactants) into a reaction chamber to deposit a layer over a substrate and include processing techniques, such as atomic layer deposition (ALD), cyclical chemical vapor deposition (cyclical CVD), and hybrid cyclical deposition processes that include an ALD component and a cyclical CVD component. In some cases, an inert gas and/or one or more reactants can continuously flow during multiple cycles of a cyclical process and a precursor can be pulsed. In accordance with examples of the disclosure, the method includes a thermal cyclical deposition process. Such a process does not include use of a plasma or the like to excite the precursor and/or reactant. Rather, such processes typically employ a substrate heater or other heater to drive the desired reactions.

As used herein, the term molecular layer deposition (MLD) may refer to a vapor deposition process in which deposition cycles, preferably a plurality of consecutive deposition cycles, are conducted in a process chamber. Typically, during each cycle an organic precursor is chemisorbed to a deposition surface (e.g., a substrate surface or a previously deposited underlying surface, such as material from a previous MLD cycle), typically forming a single molecular layer that does not readily react with additional organic precursor (i.e., a self-limiting reaction). Thereafter, if necessary, another precursor (e.g., another organic precursor) may subsequently be introduced into the process chamber for use in forming the desired organic material on the deposition surface. Further, purging steps may also be utilized during each cycle to remove excess organic precursor from the process chamber and/or remove reaction byproducts from the process chamber after formation of the desired organic material.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. For example, the term about can refer to +/−20, 10, 5, 2, or 1 percent of a value. Further, in this disclosure, the terms including, constituted by and having and their equivalents can refer independently to typically or broadly comprising, comprising, consisting essentially of, or consisting of in some embodiments. In accordance with aspects of the disclosure, any defined meanings of terms do not necessarily exclude ordinary and customary meanings of the terms.

A number of example materials are given throughout the embodiments of the current disclosure. It should be noted that the chemical formulas given for each of the example materials should not be construed as limiting and that the non-limiting example materials given should not be limited by a given example stoichiometry.

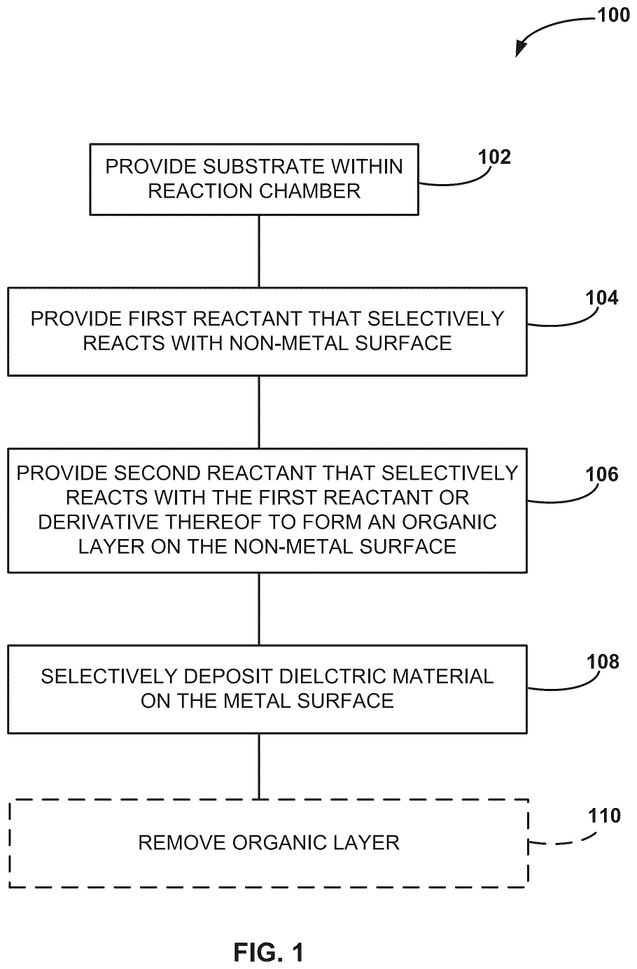

Turning now to the figures, FIG. 1 illustrates a method 100 of selectively depositing a dielectric material on a metal surface relative to a non-metal surface in accordance with embodiments of the disclosure. Method 100 includes the steps of providing the substrate within a reaction chamber of a reactor (step 102), providing a first reactant to the reaction chamber (step 104), providing a second reactant to the reaction chamber (step 106), and selectively depositing the dielectric material on the metal surface (step 108).

During step 102, a substrate is provided within a reaction chamber. The substrate includes a surface that includes a metal surface and a non-metal surface. As noted above, the metal surface can include a native oxide.

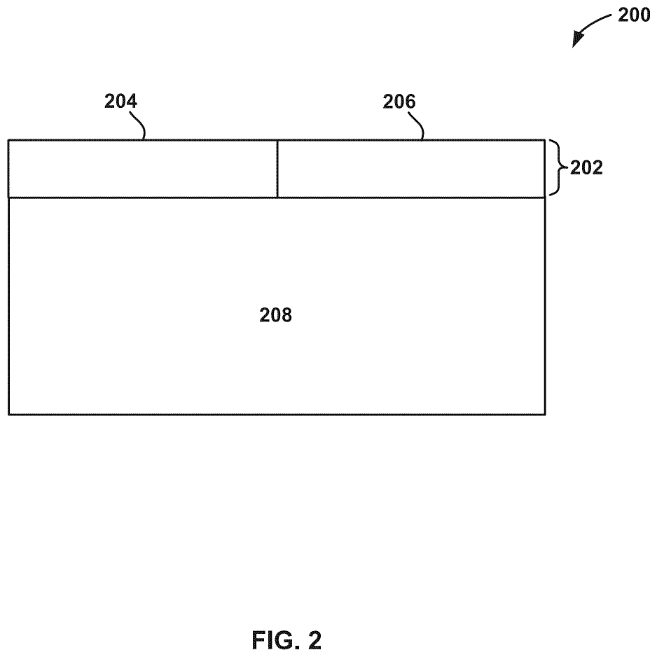

FIG. 2 illustrates an exemplary substrate 200 suitable for use with various embodiments of the disclosure. Substrate 200 includes a surface 202 that includes a metal surface 204 and a non-metal surface 206. In accordance with examples of the disclosure, non-metal surface 206 comprises —OH terminal groups. In the illustrated example, substrate 200 also includes bulk material 208. As noted above, substrates can also include various layers and topologies that are not separately illustrated.

The reaction chamber used during step 102 can be or include a reaction chamber of a chemical vapor deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between about 20° C. and about 800° C., less than 650° C., less than 600° C., less than 550° C., less than 500° C., between about 300° C. and 600° C., between about 300° C. and 650° C., between about 300° C. and 550° C., between about 300° C. and 500° C., or between about 100° C. and 300° C.

In addition to controlling the temperature of the substrate, a pressure within the reaction chamber may also be regulated. For example, in some embodiments of the disclosure, the pressure within the reaction chamber during step 102 and/or at a beginning of step 104 may be less than 1200 Torr or less than 760 Torr or between about 0.001 and about 300 Torr, about 5 and about 250 Torr, or about 1 and about 70 Torr.

During step 104, a first reactant is provided to the reaction chamber. During this step, the first reactant selectively reacts with the non-metal surface (e.g., the terminal —OH groups thereon), relative to the metal surface, to form —OSiH functional groups on the non-metal surface.

A temperature during step 104 can be as described above in connection with step 102. A pressure within the reaction chamber can also be as described above in connection with step 102. A flowrate of the first reactant, alone, can be between about 0.01 and about 1000 sccm or between about 1 and about 5 sccm. A flowrate of the first reactant with a carrier gas can be between about 1 sccm and about 50 SLM or between about 2 sccm and about 5 SLM or between about 1 SLM and about 5 SLM. A duration of step 104 can be between about 0.1 seconds and about 3 hours, between about 0.1 seconds and about 2 hours, or between about 0.1 seconds and about 300 seconds. In some cases, step 104 can include a soak process, in which a throttle valve between the reaction chamber and a vacuum source is at least partially closed during step 104. In some cases, a pressure within the reaction chamber is allowed to build during step 104. In some cases, the first reactant can be periodically pulsed to the reaction chamber during the soak period to refresh the first reactant. In some cases, the reaction chamber can be periodically pumped down during the soak period.

In accordance with examples of the disclosure, the first reactant is or includes an amino silane. Exemplary amino silanes suitable for use with step 104 include a silicon bonded to at least one nitrogen and at least one hydrogen. Particular examples of suitable amino silanes include an amino silane selected from one or more of the group consisting of (dimethylamino) silane (DMAS), bis(dimethylamino)silane (BDMAS), bis(ethylmethylamino)silane (BEMAS), bis(tertbutylamino)silane (BTBAS), tris(dimethylamino)silane (TDMAS), and di-isopropylaminosilane (DIPAS), (dimethylamino)methylsilane, (dimethylamino)dimethylsilane, any combination thereof, and the like.

The first reactant can be provided to the reaction chamber using a carrier gas. Suitable carrier gases include inert gases, such as argon, helium, nitrogen, any combination thereof, and the like.

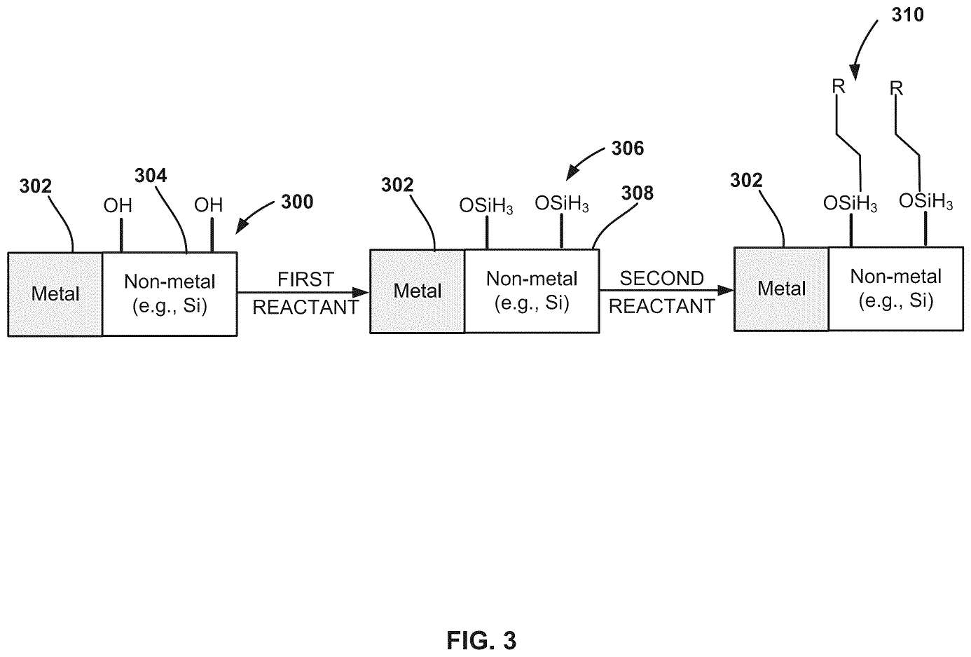

At the completion of step 104, —OSiH functional groups are selectively formed on the non-metal surface, compared to the metal surface. FIG. 3 illustrates a substrate surface 300 that includes a metal surface 302 and a non-metal surface 304. During step 104, substrate surface 300 is exposed to the first reactant, which selectively reacts with the (e.g., —OH terminated) non-metal surface 304 to form surface 306, which includes metal surface 302 and —OSiH functional group terminated surface 308.

During step 106, a second reactant is provided. Steps 104 and 106 together can be considered a molecular layer deposition process. The second reactant selectively reacts with the —OSiH functional groups formed on the substrate surface during step 104, relative to the metal surface, to selectively form an organic layer on the non-metal surface, relative to the metal surface. Step 106 can be performed within the same reaction chamber used during steps 102 and 104 or can be performed in a separate reaction chamber—e.g., another reaction chamber of the same cluster tool. If within the same reaction chamber, method 100 can include a purge step between steps 104 and 106. The purge step can include providing an inert gas to the reaction chamber. The second reactant can be provided to a/the reaction chamber with the aid of a carrier gas.

A temperature during step 106 can be as noted above in connection with steps 102 and 104. A pressure within the reaction chamber during step 106 can also be as noted above in connection with steps 102 and 104. A duration of step 106 can be as noted above in connection with step 104. A flowrate of the second reactant can be as noted above in connection with the first reactant. In some cases, a catalyst is not used to drive the reaction during step 106.

In accordance with various examples of the disclosure, the second reactant is or includes an organic compound. For example, the second reactant can be or include an organic compound having at least one alkene or an alkyne terminal functional group, a terminal aldehyde group, and/or a terminal alcohol group and/or be or include an organo-sulfur compound, such as a thiol or a disulfide compound.

By way of examples, the second reactant be or include a C2-C18, C2-C10, or C2-C8 linear or branched or cyclic hydrocarbon or fluorine-substituted derivative thereof that includes a terminal alkene functional group or a terminal alkyne functional group or a C1-C18, C2-C10, or C2-C8 linear or branched or cyclic hydrocarbon or fluorine-substituted derivative thereof that includes a terminal aldehyde group and/or a terminal alcohol group. The aldehydes can be represented by the formula:

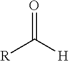

where R is a C1-C18 linear or branched or cyclic hydrocarbon or fluorine derivative thereof. The aldehyde can be represented by the formula CₙH₂ₙ₊₁OH, where n is between 1 and 18 or a fluorine derivative thereof.

In accordance with some of these examples, the second reactant can be represented by the formula CₓH_{y}OₐF_{z}, where X is a whole number between about 2 and about 24 or between about 2 and about 18 or between about 2 and about 12, y is a whole number between about 0 and about 36 or between about 1 and about 24 or between about 1 and about 12, a is 0 or a whole number between about 1 and about 10 or is one or two, and z is 0 or a whole number between about 0 and about 36 or between about 1 and about 24 or between about 1 and about 12. In such cases, when a is 0, the second reactant can be or include a hydrocarbon or fluorine derivative thereof.

In accordance with further examples, the second reactant can be or include a thiol represented by the formula R—SH, wherein R is a C1-C18, C2-C10, or C2-C8 linear or branched or cyclic hydrocarbon or fluorine-substituted derivative thereof. In accordance with further examples, the second reactant can be or include a disulfide represented by the formula R′—S—S—R″, wherein each R′ and R″ is independently a C1-C18, C2-C10, or C2-C8 linear or branched or cyclic hydrocarbon or fluorine-substituted derivative thereof.

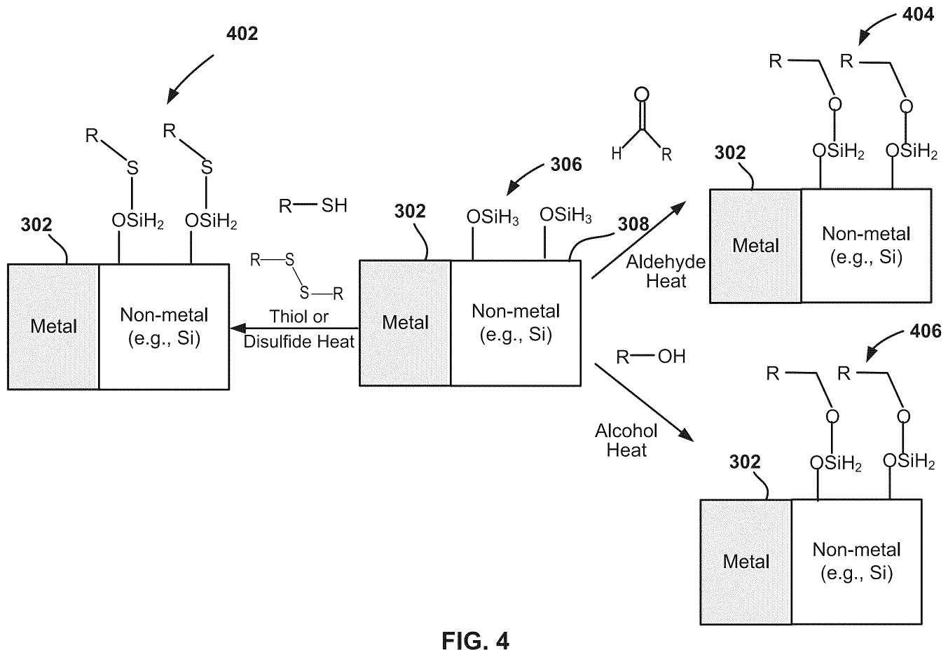

Returning again to FIG. 3, when the second reactant includes the alkene or alkyne terminal functional group, an organic layer 310 selectively forms on non-metal, —OSiH₃ surface 308. FIG. 4 illustrates examples of thiol, disulfide, aldehyde, and alcohol second reactants. In the case of thiol and disulfide second reactants, an organo-sulfur layer 402 is formed, where R can be as defined above. In the case of aldehyde second reactants, an organic layer 404 is formed, where R can be as defined above. In the case of alcohol second reactants, an organic layer 406 is formed, where R can be as defined above.

In some embodiments, the selectively deposited organic layer on the non-metal surface of the substrate may have a thickness less than 50 nanometers, or less than 20 nanometers, or less than 10 nanometers, or less than 5 nanometers, or less than 3 nanometers, or less than 2 nanometers, or less than 1 nanometer, or between approximately 1 nanometer and 50 nanometers. In some embodiments, the ratio of material deposited on the non-metal surface relative to the metal surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1.

During step 108, the dielectric material is selectively deposited onto the metal surface relative to the organic layer/non-metal surface. The dielectric material can be, for example, a material having a dielectric constant greater than 3.9 or greater than a dielectric constant of silicon oxide. In accordance with examples of the disclosure, the dielectric material is or includes a metal oxide, nitride, or carbide or a metalloid oxide, nitride, or carbide. The metal can be, for example, a transition or post transition metal, such as aluminum, hafnium, yttrium, titanium, tantalum, titanium nitride, molybdenum, tungsten, combinations thereof or the like. The metalloid can be or include, for example, silicon, germanium, arsenic, or the like. Step 108 can be or include a cyclical deposition process that includes providing a metal or metalloid precursor and a reactant to the reaction chamber.

In some embodiments, the deposition of dielectric material only occurs on the metal surface and does not occur on the organic layer/non-metal surface. In some embodiments, deposition of the dielectric material on the metal surface relative to the organic layer/non-metal surface is at least about 80%. In some embodiments, deposition of the dielectric material on the metal surface relative to the organic layer/non-metal surface is at least about 90%. In some embodiments, deposition of the dielectric material on the metal surface relative to the organic layer/non-metal surface is at least about 98%. In some cases, the selectivity can be about 100% to a thickness of greater than 5 nm, greater than 10 nm, or greater than 15 nm.

As illustrated in FIG. 1, method 100 can also include a step of removing the organic layer. The organic layer can be removed after the step of selectively depositing the dielectric material on the metal surface. Step 110 can include a plasma process. By way of examples, step 110 can include a hydrogen and/or nitrogen and/or oxygen based direct, indirect, or remote plasma process or the like.

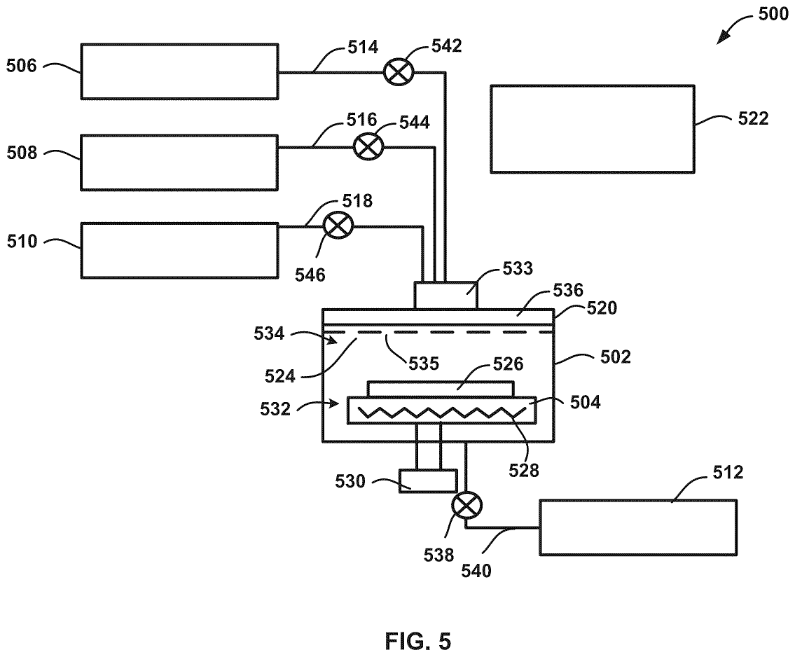

FIG. 5 illustrates an exemplary reactor system 500 in accordance with additional exemplary embodiments of the disclosure. Reactor system 500 includes a reactor 502, a susceptor 504, gas sources 506-510, a gas distribution device 520, vacuum source 512, and controller 522. Although not illustrated, reactor system 500 may additionally include direct and/or remote plasma and/or thermal excitation apparatus for one or more reactants and/or within reactor 502.

Reactor 502 can include a reaction chamber 524 suitable for gas-phase reactions. Reactor 502 can be formed of suitable material, such as quartz, metal, or the like, and can be configured to retain one or more substrates for processing. Reactor system 500 can include any suitable number of reactors 502 and can optionally include one or more substrate handling systems. Reactor 502 can be a standalone reactor or part of a cluster tool.

Reactor 502 can be configured as a cyclical deposition process reactor (e.g., a cyclical CVD reactor), an ALD reactor, or the like. Reactor 502 can be configured to deposit a variety of films or layers, such as the organic and dielectric material layers noted above.

Susceptor 504 is configured to retain substrate 526 in place during processing. One or more sections of susceptor 504 can be heated, cooled, or be at ambient process temperature during processing. In accordance with examples of the disclosure, susceptor 504 includes a temperature regulating device 528, such as a heater (e.g., a resistive heater), and/or a cooling device (e.g., a conduit for a cooling medium, such as chilled water).

In the illustrated example, reactor system 500 includes a mechanism 530 to move susceptor 504 from a lower chamber region 532 to an upper chamber region 534. Mechanism 530 can include any suitable apparatus capable of moving susceptor 504. By way of example, mechanism 530 includes a servo motor to drive susceptor 504 along a vertical axis. Mechanism 530 can suitably reside outside reaction chamber 524.

Susceptor 504 can be formed of any suitable material, such as ceramic material, such as boron nitride, aluminum nitride, quartz, and ceramic-coated materials, such as ceramic-coated metals. Susceptor 504 can also include resistive heating material. Exemplary materials suitable for resistive heating material include tungsten (W), nichrome (NiCr), cupronickel (CuNi), graphite, molybdenum disilicide (MoSi₂) or any other suitable heater material. The resistive heating material can be coated onto (e.g., patterned onto), for example, ceramic or ceramic-coated metal. Susceptor 504 can include an additional protective layer formed overlying the resistive heating material. The protective layer can be formed of, for example, ceramic material.

Gas sources 506-510 can include any suitable vessels and respective material contained therein. By way of examples, gas source 506 can include the first reactant, gas source 508 can include the second reactant, and gas source 510 can include an inert gas. Gas sources 506-510 can be coupled to reaction chamber 524 via gas distribution device 520.

Gas distribution device 520 is configured to receive and facilitate distribution of one or more gases to reaction chamber 524 during substrate processing. Gas distribution device 520 can include an inlet 533 and a plurality of holes 535 coupled to a plenum 536.

Vacuum source 512 can include one or more vacuum sources. Exemplary vacuum sources include one or more dry vacuum pumps and/or one or more turbomolecular pumps. A (e.g., throttle) valve 538 can be in a line that fluidly couples reaction chamber 524 to vacuum source 512.

Controller 522 can be configured to perform various functions and/or steps as described herein. For example, controller 522 can be configured to perform the method described in connection with FIG. 1. Controller 522 can include one or more microprocessors, memory elements, and/or switching elements to perform the various functions. Although illustrated as a single unit, controller 522 can alternatively comprise multiple devices. By way of examples, controller 522 can be used to control gas flow of one or more gases from sources 506-510 via one or more of lines 514, 516, 518 and valves 542, 544, 546, to move susceptor 504 between a first position, to control a pressure within reaction chamber 524 (e.g., using valve 538), and/or to provide a first reactant and/or a second reactant (e.g., using one or more of valves 542-546) as described herein.

Although exemplary embodiments of the present disclosure are set forth herein, it should be appreciated that the disclosure is not so limited. For example, although the reactors, systems, and methods are described in connection with various specific configurations, the disclosure is not necessarily limited to these examples. Various modifications, variations, and enhancements of the exemplary reactors, systems, and methods set forth herein may be made without departing from the spirit and scope of the present disclosure.

The subject matter of the present disclosure includes all novel and nonobvious combinations and subcombinations of the various steps, systems, reactors, components, and configurations, and other features, functions, acts, and/or properties disclosed herein, as well as any and all equivalents thereof.

1. A method of selectively depositing a dielectric material on a metal surface relative to a non-metal surface, the method comprising:
providing a substrate within a reaction chamber of a reactor;
providing a first reactant to the reaction chamber, wherein the first reactant selectively reacts with the non-metal surface, relative to the metal surface, to form —OSiH functional groups on the non-metal surface; and
providing a second reactant,
wherein the second reactant selectively reacts with the —OSiH functional groups, relative to the metal surface, to selectively form an organic layer on the non-metal surface, relative to the metal surface.

2. The method of claim 1, wherein the first reactant comprises an amino silane.

3. The method of claim 2, wherein the amino silane comprises a silicon bonded to at least one nitrogen and at least one hydrogen.

4. The method of claim 1, wherein the metal surface comprises a metallic material.

5. The method of claim 1, wherein the metal surface consists essentially of one or more of a metal or a metal alloy.

6. The method of claim 1, wherein the second reactant comprises an alkene or an alkyne terminal functional group.

7. The method of claim 1, wherein the second reactant comprises a C2-C18, C2-C10, or C2-C8 linear or branched or cyclic hydrocarbon or fluorine-substituted derivative thereof.

8. The method of claim 1, wherein the second reactant is represented by the formula CₓH_{y}F_{z}, where X is a whole number between about 2 and about 24, y is a whole number between 0 and about 36, and z is a whole number between 0 and about 36.

9. The method of claim 1, wherein the second reactant comprises one or more of a thiol or a disulfide.

10. The method of claim 9, wherein the thiol is represented by the formula R—SH, wherein R is a C1-C18 linear or branched or cyclic hydrocarbon or fluorine-substituted derivative thereof.

11. The method of claim 9, wherein the disulfide is represented by the formula R′—S—S—R″, wherein each R′ and R″ is independently a C1-C18 linear or branched or cyclic hydrocarbon or fluorine-substituted derivative thereof.

12. The method of claim 1, wherein the second reactant comprises one or more of an alcohol or an aldehyde.

13. The method of claim 12, wherein the aldehyde is represented by the formula: 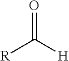
and where R is a C1-C18 linear or branched or cyclic hydrocarbon.

14. The method of claim 12, wherein the aldehyde is represented by the formula CₙH₂ₙ₊₁OH, where n is between 1 and 18.

15. The method of claim 1, wherein the dielectric material is a metal oxide, nitride, or carbide or a metalloid oxide, nitride, or carbide.

16. The method of claim 1, further comprising selectively depositing the dielectric material on the metal surface.

17. The method of claim 16, further comprising, after selectively depositing the dielectric material on the metal surface, removing the organic layer.

18. A method of selectively depositing a dielectric material on a metal surface relative to a non-metal surface, the method comprising:
providing a substrate within a reaction chamber of a reactor;
providing a first reactant to the reaction chamber, wherein the first reactant selectively reacts with the non-metal surface, relative to the metal surface, to form —OSiH functional groups on the non-metal surface; and
providing a second reactant to the reaction chamber,
wherein the first reactant comprises an amino silane,
wherein the second reactant comprises one or more of (1) a C2-C18 alkene or alkyne of fluorine-substituted derivative thereof, (2) an organo-sulfur compound, (3) an alcohol, or (4) an aldehyde, and
wherein the second reactant selectively reacts with the —OSiH functional groups, relative to the metal surface, to selectively form an organic layer on the non-metal surface, relative to the metal surface.

19. The method of claim 18, further comprising selectively depositing the dielectric material on the metal surface.

20. A reactor system comprising:
a controller configured to perform the method of claim 1;
a source vessel comprising the first reactant and coupled to the reaction chamber;
a source vessel comprising the second reactant and coupled to the reaction chamber;
the reactor; and
a vacuum source.
